(19) United States
(12) Patent Application Publication
(10) Pub. No.: US 2023/0268281 A1
(43) Pub. Date: Aug. 24, 2023

(54) SEMICONDUCTOR DEVICE AND MANUFACTURING METHOD THEREOF

(71) Applicant: Kioxia Corporation, Tokyo (JP)

(72) Inventor: Hiroyuki WAKIOKA, Yokkaichi Mie (JP)

(73) Assignee: Kioxia Corporation, Tokyo (JP)

(21) Appl. No.: 17/940,933

(22) Filed: Sep. 8, 2022

(30) Foreign Application Priority Data
Feb. 22, 2022 (JP) 2022-025975

(51) Int. Cl. H01L 23/538; H01L 25/10; H01L 23/31; H01L 21/48; H01L 21/56

(52) U.S. Cl. CPC H01L 23/5386; H01L 25/105; H01L 23/3128; H01L 23/5383; H01L 23/5389; H01L 21/4853; H01L 21/4857; H01L 21/565; H01L 2225/1035; H01L 2225/1058

(57) ABSTRACT

A semiconductor device according to the present embodiment includes a first substrate, a resin layer, and a wire. The first substrate has a first face. The resin layer is provided on the first face and has a second face on an opposite side to the first face. The wire is provided so as to penetrate the resin layer and protrude from the second face. The wire includes a large-width part which is provided at an end of the wire protruding from the second face and which is wider than a width of the wire penetrating the resin layer. The large-width part is arranged so as to come into contact with the second face.

### CROSS REFERENCE TO RELATED APPLICATIONS

This application is based upon and claims the benefit of priority from the prior Japanese Patent Application No. 2022-025975, filed on Feb. 22, 2022, the entire contents of which are incorporated herein by reference.

### FIELD

The embodiments of the present invention relate to a semiconductor device and a manufacturing method thereof.

### BACKGROUND

In a semiconductor package, a PoP (Package on Package) structure in which a plurality of packages are stacked may sometimes be used. In a PoP structure, packages are connected to each other by, for example, solder. For example, when a sufficient connection area cannot be obtained, there is a possibility of breakage of a connection between the packages.

### BRIEF DESCRIPTION OF THE DRAWINGS

FIG. 1 is a cross sectional view showing an example of a configuration of a semiconductor device according to a first embodiment;

FIG. 2 is a cross sectional view showing an example of a configuration of an end of a wire according to the first embodiment;

FIG. 3A is a cross sectional view showing an example of a manufacturing method of a semiconductor device according to the first embodiment;

FIG. 3B is a cross sectional view showing an example of a manufacturing method of a semiconductor device that is a continuation of FIG. 3A;

FIG. 3C is a cross sectional view showing an example of a manufacturing method of a semiconductor device that is a continuation of FIG. 3B;

FIG. 3D is a cross sectional view showing an example of a manufacturing method of a semiconductor device that is a continuation of FIG. 3C;

FIG. 3E is a cross sectional view showing an example of a manufacturing method of a semiconductor device that is a continuation of FIG. 3D;

FIG. 3F is a cross sectional view showing an example of a manufacturing method of a semiconductor device that is a continuation of FIG. 3E;

FIG. 4 is a cross sectional view showing an example of a configuration of an end of a wire according to a second embodiment;

FIG. 5 is a cross sectional view showing an example of a formation method of an end of a wire according to the second embodiment;

FIG. 6 is a cross sectional view showing an example of a configuration of an end of a wire according to a third embodiment; and

FIG. 7 is a cross sectional view showing an example of a formation method of an end of a wire according to the third embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction perpendicular to a surface of a wiring substrate on which semiconductor chips are provided is assumed as “an upper direction”. Therefore, the term “upper direction” or “lower direction” occasionally differs from an upper direction or a lower direction based on a gravitational acceleration direction. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a first substrate, a resin layer, and a wire. The first substrate has a first face. The resin layer is provided on the first face and has a second face on an opposite side to the first face. The wire is provided so as to penetrate the resin layer and protrude from the second face. The wire includes a large-width part which is provided at an end of the wire protruding from the second face and which is wider than a width of the wire penetrating the resin layer. The large-width part is arranged so as to come into contact with the second face.

### FIRST EMBODIMENT

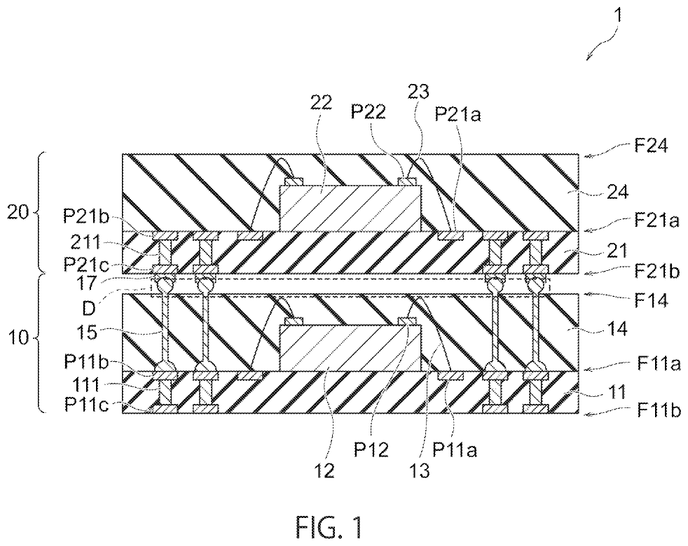

FIG. 1 is a cross sectional view showing an example of a configuration of a semiconductor device 1 according to a first embodiment. For example, the semiconductor device 1 has a structure in which a plurality of packages are stacked. The semiconductor device 1 includes stacked packages 10 and 20.

Next, a configuration of the package 10 will be described.

The package 10 includes a wiring substrate 11, a semiconductor chip 12, a wire 13, a resin layer 14, and a wire 15.

For example, the wiring substrate 11 is a substrate such as a printed circuit board. The wiring substrate 11 has a face F11a (first face), a face F11b, pads P11a to P11c, a via 111, and a wiring layer (not illustrated).

The face F11b is a face on an opposite side to the face F11a. The pad P11a is provided on the face F11a and is connected to the wire 13. The pad P11b is provided on the face F11a and is connected to the wire 15. The pad P11c is provided on the face Flub. The via 111 is provided so as to penetrate the wiring substrate 11 from the face F11a to the face F11b of the wiring substrate 11 and electrically connects the pad P11b and the pad P11c to each other.

A conductive material is used as materials of the pads P11a to P11c and the via 111.

For example, the semiconductor chip 12 is a memory chip of a NAND flash memory, a controller chip that controls a memory chip, or a semiconductor chip mounted with any LSI (Large Scale Integration). The semiconductor chip 12 has a pad P12 on a top surface thereof. A conductive material is used as a material of the pad P12.

In addition, the semiconductor chip 12 is provided on the face F11a. For example, the semiconductor chip 12 is covered by the resin layer 14. The semiconductor chip 12 is electrically connected to the wire 15 via, for example, the pad P12, the wire 13, the pad P11a, wiring (not illustrated) inside the wiring substrate 11, and the pad P11b. The semiconductor chip 12 may be stacked in two or more stages.

The wire 13 is, for example, a looped wire. The wire 13 electrically connects the pad P12 and the pad P11a to each other. For example, a conductive metal such as Au is used as a material of the wire 13.

The resin layer 14 is provided on the face F11a of the wiring substrate 11. The resin layer 14 has a face F14 (a second face) on an opposite side to the wiring substrate 11. For example, the resin layer 14 is a sealing material such as a dielectric sealing material.

For example, as the resin layer 14, a resin such as a phenolic resin, a polyimide resin, a polyamide resin, an acrylic resin, an epoxy resin, a PBO (p-phenylenebenzobisoxazole) resin, a silicone resin, or a benzocyclobutene resin, or an organic insulation material such as a mixed material, a composite material of these resins is used.

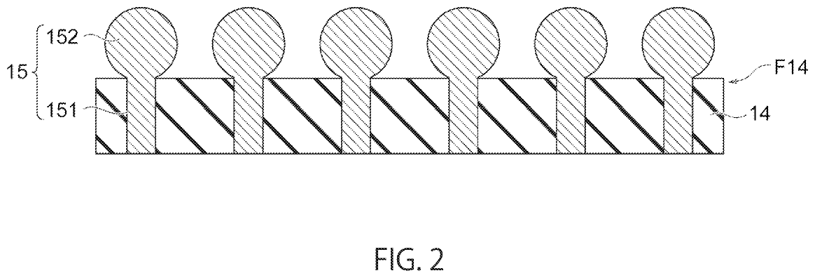

The wire 15 is provided so as to penetrate the resin layer 14. For example, the wire 15 is provided so as to penetrate the resin layer 14 from the pad P11b and protrude from the face F14. For example, the wire 15 is a columnar electrode provided so as to extend in a direction approximately perpendicular to the face F11a. The wire 15 electrically connects the wiring substrate 11 of the package 10 and a wiring substrate 21 of the package 20 to each other. For example, a conductive material such as Au is used as a material of the wire 15. Details of an upper end of the wire 15 to connect to the wiring substrate 21 will be described later with reference to FIG. 2.

Next, a configuration of the package 20 will be described.

The package 20 is provided on top of the package 10 so as to oppose the face F14 of the resin layer 14. The package 20 includes the wiring substrate 21, a semiconductor chip 22, a wire 23, and a resin layer 24.

For example, the wiring substrate 21 is a substrate such as a printed circuit board. The wiring substrate 21 has a face F21a, a face F21b, pads P21a to P21c, a via 211, and a wiring layer (not illustrated).

The face F21b is a face on an opposite side to the face F21a. Configurations of the pads P21a to P21c and the via 211 are approximately similar to, for example, corresponding configurations of the pads P11a to P11c and the via 111 in the package 10.

The wiring substrate 21 is provided so as to oppose the face F14 of the resin layer 14. In addition, solder 17 is provided between the upper end of the wire 15 and the pad P21c of the wiring substrate 21. Alternatively, an alloy layer may be formed at a connection between the wire 15 and the solder 17.

A configuration of the semiconductor chip 22 is approximately similar to, for example, a corresponding configuration of the semiconductor chip 12 in the package 10. The semiconductor chip 22 has a pad P22 on a top surface thereof. A conductive material is used as a material of the pad P22. The semiconductor chip 22 may be stacked in two or more stages.

A configuration of the wire 23 is approximately similar to, for example, a corresponding configuration of the wire 13 in the package 10.

A configuration of the resin layer 24 is approximately similar to, for example, a corresponding configuration of the resin layer 14 in the package 10.

Next, a configuration of the upper end of the wire 15 will be described.

FIG. 2 is a cross sectional view showing an example of a configuration of an end of the wire 15 according to the first embodiment. FIG. 2 is an enlarged view of a dotted frame D shown in FIG. 1. In addition, FIG. 2 shows six wires 15.

The wire 15 includes a penetration part 151 and a large-width part 152.

The penetration part 151 is a portion of the wire 15 that penetrates the resin layer 14. In other words, a circumference of the penetration part 151 is covered by the resin layer 14.

The large-width part 152 is provided at the end of the wire 15 that protrudes from the face F14 of the resin layer 14. The large-width part 152 has a larger width than that of the penetration part 151. The width of the large-width part 152 is a width in a direction approximately parallel to the face F11a (the face F14). The large-width part 152 is arranged so as to come into contact with the face F14. Therefore, the width of the penetration part 151 that is surrounded by the resin layer 14 is approximately constant and the wire 15 becomes wider from a position where the wire 15 protrudes from the face F14 of the resin layer 14.

While an example of a shape of the large-width part 152 is an approximately spherical shape, the large-width part 152 is not limited thereto and may have a different shape.

A plurality of the large-width parts 152 are electrically connected to the wiring substrate 21 which is provided so as to oppose the face F14 as shown in FIG. 1. As described above, for example, the large-width part 152 is connected to the pad P21c of the wiring substrate 21 by the solder 17. By providing the large-width part 152, a contact area between the large-width part 152 and the solder 17 or, in other words, a connection area between the wire 15 and the solder 17 can be increased. Accordingly, reliability of connection can be improved.

In the example shown in FIG. 2, a size of the plurality of the large-width parts 152 is approximately the same regardless of a position on the face F14. In other words, a variation in sizes of the plurality of the large-width parts 152 is small.

Next, a manufacturing method of the semiconductor device 1 will be described.

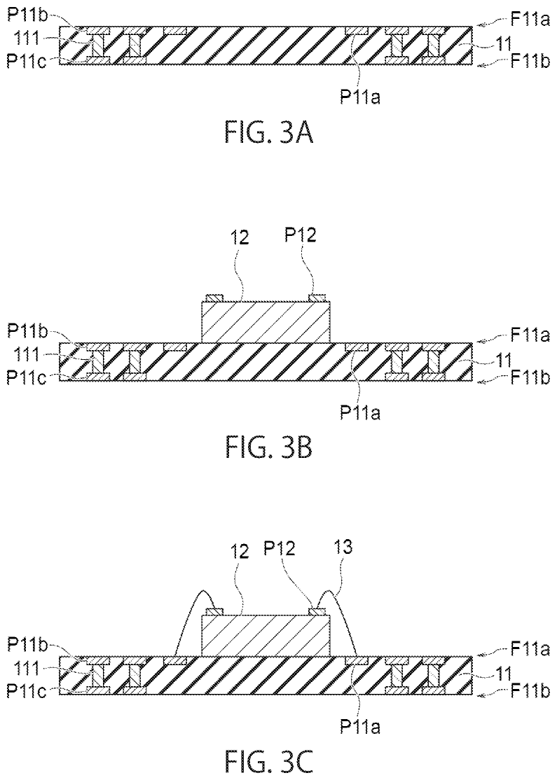

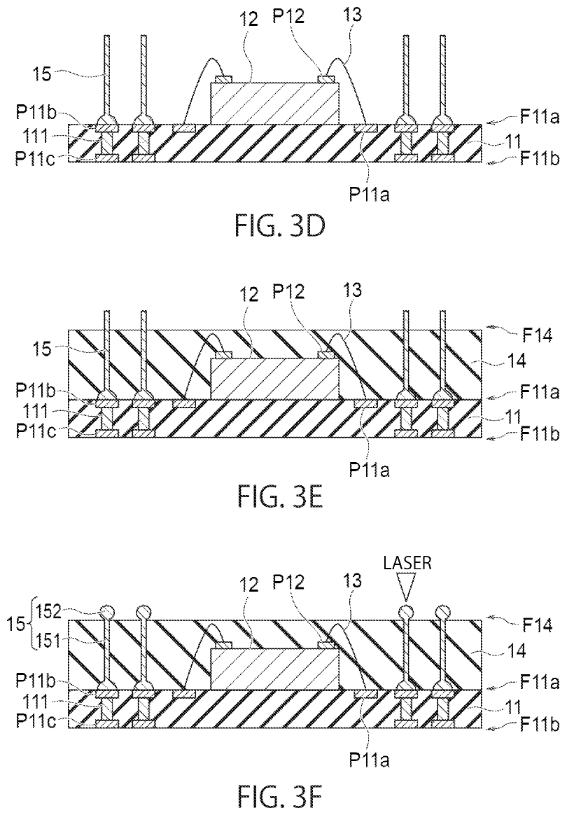

FIGS. 3A to 3F are cross sectional views showing an example of a manufacturing method of the semiconductor device 1 according to the first embodiment. Hereinafter, a manufacturing method of the package will be mainly described.

First, as shown in FIG. 3A, the wiring substrate 11 is prepared. The pads P11a to P11c and the via 111 are formed on the wiring substrate 11.

Next, as shown in FIG. 3B, the semiconductor chip 12 is provided on the face F11a of the wiring substrate 11 (chip mount).

Next, as shown in FIG. 3C, the wire 13 is formed. The wire 13 is formed so as to electrically connect the pad P12 of the semiconductor chip 12 and the pad P11a of the wiring substrate 11 to each other.

Next, as shown in FIG. 3D, the wire 15 is formed above the face F11a of the wiring substrate 11. For example, the wire 15 is formed so as to extend in a direction approximately perpendicular to the face F11a from the pad P11b.

Next, as shown in FIG. 3E, the resin layer 14 is formed. More specifically, the resin layer 14 having the face F14 on an opposite side to the wiring substrate 11 is formed on the face F11a so that the end of the wire 15 becomes exposed. The resin layer 14 is formed so as to cover a portion of the wire 15 other than the upper end and to cover the semiconductor chip 12. For example, the upper end of the wire 15 is exposed from the resin layer 14 by arranging a film that can be penetrated by the upper end of the wire 15 inside a mold for forming the resin layer 14.

Next, as shown in FIG. 3F, the large-width part 152 is formed at a tip (upper end) of the wire 15. More specifically, the large-width part 152 having a larger width than the width of the wire 15 (the penetration part 151) that penetrates the resin layer 14 is formed at the end of the wire 15 that is exposed from the face F14. For example, the large-width part 152 is formed by melting an end of the wire 15 by a laser. The upper end of the melted wire 15 becomes approximately spherical due to surface tension. Subsequently, the melted wire 15 is cooled and the large-width part 152 with an approximately spherical shape is formed.

Melting of the end of the wire 15 is not limited to the use of a laser and may be performed by electric discharge and the like. In addition, the method of forming the large-width part 152 may be a method other than melting.

Furthermore, since the large-width part 152 is formed after forming the resin layer 14, a lower end of the large-width part 152 comes into contact with the face F14. This is because the end of the wire 15 is melted to the position of the face F14. Accordingly, an amount of the end of the wire 15 to be melted is determined by the position of the face F14. As a result, the large-width part 152 can be formed so as to reduce a variation in sizes among the plurality of the large-width parts 152.

In the step shown in FIG. 3F, the package 10 is completed. Subsequently, by providing the package 20 on top of the package 10, the semiconductor device 1 described in FIG. 1 is completed. For example, the large-width part 152 is connected to the pad P21c of the wiring substrate 21 inside the package 20 by the solder 17.

Alternatively, prior to the step shown in FIG. 3F, the upper end of the wire 15 may be ground by, for example, a milling machine to make a height of the wire 15 uniform. Accordingly, the size of the large-width part 152 can be made approximately the same regardless of a position on the face F14. In other words, a variation in sizes of the large-width parts 152 can be reduced.

As described above, according to the first embodiment, the wire 15 includes the large-width part 152. The large-width part 152 is provided at the end of the wire 15 that is exposed from the face F14 and has a larger width than the width of the wire 15 (the penetration part 151) that penetrates the resin layer 14. Accordingly, a connection area between the wire 15 and the solder 17 can be increased. As a result, reliability of connection can be improved.

In addition, in the first embodiment, as shown in FIG. 2, the large-width part 152 is arranged so as to come into contact with the face F14 of the resin layer 14. Accordingly, when connecting the wire 15 and the wiring substrate 21 to each other, the large-width part 152 can more appropriately support the wiring substrate 21 (the package 20).

In addition, the large-width part 152 is integrally configured with the penetration part 151 using a same material. In other words, a connection does not exist between the large-width part 152 and the penetration part 151. Accordingly, strength can be improved at the face F14 that is susceptible to stress concentration. As a result, reliability of connection can be improved.

As a comparative example, a case where the large-width part 152 is not provided will be described. When the large-width part 152 is not provided, a contact area between the wire 15 and the solder 17 is determined by a width of the wire 15 (the penetration part 151). In this case, there is a possibility that a sufficient connection area may not be obtained and breakage or the like is more likely to occur. In addition, an alloy layer is formed at the face F14 that acts as a connection between the wire 15 and the solder 17. Since the face F14 is a location that is susceptible to stress concentration, breakage due to sheer is likely to occur in the alloy layer and resistance to physical impact is likely to decline.

By comparison, in the first embodiment, providing the large-width part 152 enables the connection area between the wire 15 and the solder 17 to be increased. Accordingly, breakage of the connection between the wire 15 and the solder 17 can be suppressed. In addition, instead of the connection (alloy layer) between the wire 15 and the solder 17, the wire 15 of a same material from the penetration part 151 to the large-width part 152 is present on the face F14 that is a location susceptible to stress concentration. Accordingly, since an alloy layer is not formed on the face F14 that is a location susceptible to stress concentration, impact resistance can be improved.

In addition, in the first embodiment, the large-width part 152 is formed after forming the resin layer 14 as shown in FIGS. 3E and 3F. Accordingly, heat during the formation of the large-width part 152 can be readily released via the resin layer 14. As a result, thermal damage to the wiring substrate 11 and devices such as the semiconductor chip 12 can be reduced.

Furthermore, since the large-width part 152 is formed by melting, a variation in the height of the wire 15 can be suppressed and a package thickness (height) of the semiconductor device 1 can be reduced. There are cases where, even though the plurality of the wires 15 are formed so as to have a same height, a variation ends up being created among the actual heights of the wires 15. Due to melting, the wire 15 protruding from the face F14 decreases in height but becomes larger in a width direction. Therefore, a variation among the heights of the large-width parts 152 becomes smaller than the variation in the heights of the wires prior to melting. Accordingly, the package thickness (height) of the semiconductor device 1 can be reduced.

The semiconductor device 1 is not limited to two stages and may include packages stacked in three or more stages.

In addition, the package 20 may be a stand-alone wiring substrate. In this case, the package 10 is to be mounted on the stand-alone wiring substrate instead of a PoP (Package on Package) structure.

### SECOND EMBODIMENT

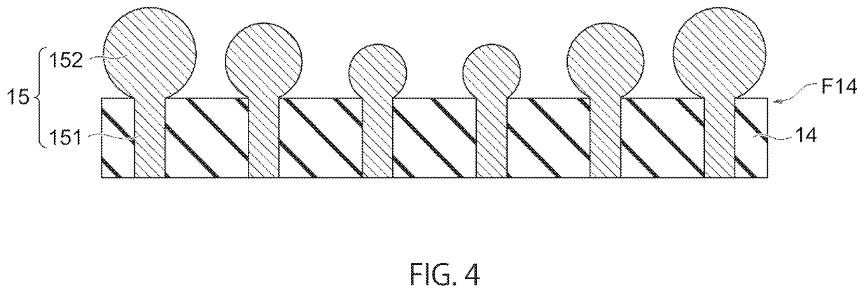

FIG. 4 is a cross sectional view showing an example of a configuration of an end of the wire 15 according to a second embodiment. The second embodiment differs from the first embodiment in that a size of the large-width part 152 differs in accordance with a position on the face F14.

The package 10 includes a plurality of the wires 15, each including the large-width part 152. The plurality of the large-width parts 152 have different sizes corresponding to positions on the face F14.

There may be cases where warpage has occurred in the wiring substrate 21 shown in FIG. 1. For example, when the wiring substrate 21 shown in FIG. 1 is warped downward, there is a possibility that a poor connection may be created between the large-width part 152 in an outer circumference and the pad P21c of the wiring substrate 21.

In consideration thereof, the plurality of the large-width parts 152 are given different heights corresponding to the warpage of the wiring substrate 21. The height of the large-width part 152 is a height in a direction approximately perpendicular to the face F11a (the face F14).

Accordingly, the wire 15 and the wiring substrate 21 can be more appropriately connected to each other. In the example shown in FIG. 4, the large-width parts 152 become higher from a center toward an outer circumference of the face F14. Note that heights of the plurality of the large-width parts 152 are not limited to those in the example shown in FIG. 4.

Since other configurations of the semiconductor device 1 according to the second embodiment are similar to corresponding configurations of the semiconductor device 1 according to the first embodiment, detailed descriptions thereof will be omitted.

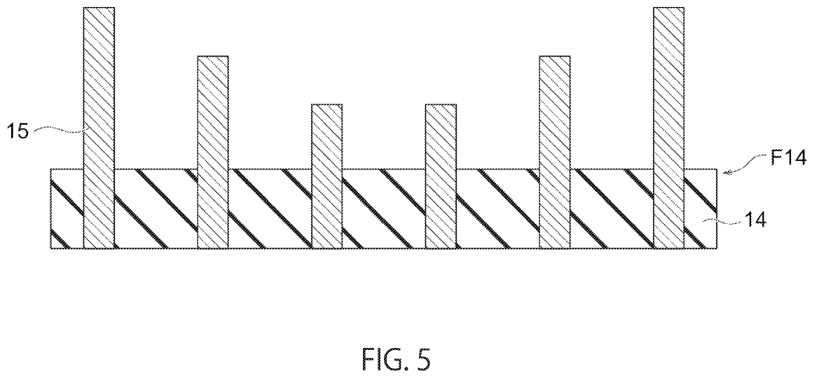

FIG. 5 is a cross sectional view showing an example of a formation method of an end of the wire 15 according to the second embodiment. FIG. 5 represents an enlarged cross sectional view in the step shown in FIG. 3E.

After forming the wire 13 (refer to FIG. 3C), the plurality of the wires 15 having different heights corresponding to positions on the face F11a are formed so that heights of the wires 15 exposed from the face F14a differ from each other. The plurality of the wires 15 are formed by varying the heights so that the heights correspond to the warpage of the wiring substrate 21 shown in FIG. 1. In the example shown in FIG. 5, the wires 15 are formed so as to become higher from a center toward an outer circumference of the face F14.

Next, the resin layer 14 is formed in a similar manner to the step shown in FIG. 3E. In the example shown in FIG. 5, the wires 15 are formed so as to become higher from a center toward an outer circumference of the face F14.

Next, the large-width part 152 having a different size corresponding to a position on the face F14 is formed at an end of each of the plurality of the wires 15. The large-width part 152 is formed by melting of a protruding portion of the wire 15. Therefore, a size of the large-width part 152 is determined by a height of the wire 15 that protrudes from the face F14 in FIG. 5.

In this manner, since the large-width part 152 is formed after forming the resin layer 14, the size (height) of the large-width part 152 can be more readily adjusted by adjusting the height of the wire 15 to be formed.

As in the second embodiment, the size of the large-width part 152 may differ in accordance with a position on the face F14. The semiconductor device 1 according to the second embodiment is capable of producing a similar effect to the first embodiment.

### THIRD EMBODIMENT

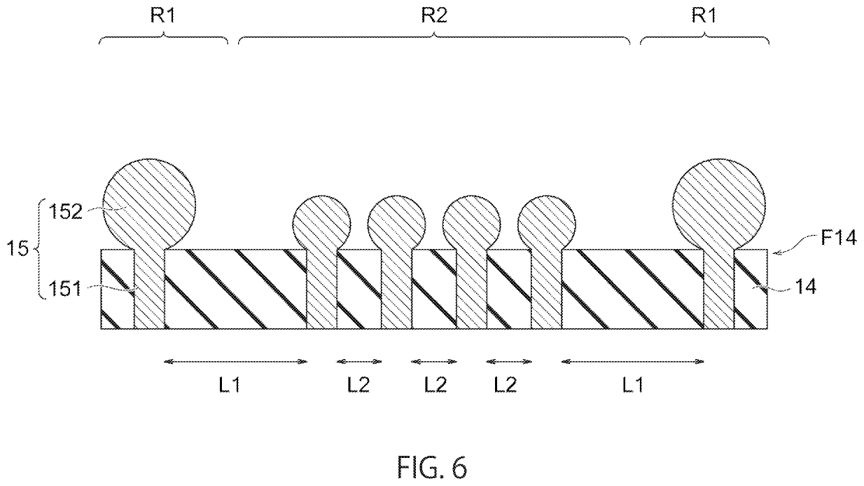

FIG. 6 is a cross sectional view showing an example of a configuration of an end of the wire 15 according to a third embodiment. The third embodiment differs from the first embodiment in that a size of the large-width part 152 differs in accordance with a position on the face F14.

A plurality of the large-width parts 152 have different widths corresponding to intervals between the wires 15 on the face F14.

The face F14 has a region R1 and a region R2. The region R2 is a region with a higher density of the wires 15 on the face F14 than the region R1. In the example shown in FIG. 6, the region R1 is a region at center of the face F14 and the region R2 is a region in, for example, an outer circumference of the face F14. Note that positions of the regions R1 and R2 are not limited to those in the example shown in FIG. 6.

A distance between adjacent wires 15 in the region R1 is a distance L1. A distance between adjacent wires 15 in the region R2 is a distance L2. The distance L2 is shorter than the distance L1.

When the width of the large-width part 152 in the region R2 becomes too large, adjacent large-width parts 152 may possibly come into contact with each other and become short-circuited.

Therefore, the width of the large-width part 152 in the region R2 is smaller than the width of the large-width part 152 in the region R1. Accordingly, the large-width parts 152 can be prevented from coming into contact with each other and becoming short-circuited in the region R2 where density is relatively high.

In addition, in the region R2, since the number of the large-width parts 152 is relatively large, even when the width of the large-width parts 152 is small, the large-width parts 152 can support the wiring substrate 21 (the package 20). On the other hand, in the region R1, since the width of the large-width parts 152 is relatively large, even when the number of the large-width parts 152 is small, the large-width parts 152 can support the wiring substrate 21 (the package 20).

Accordingly, a more appropriate connection area can be obtained in accordance with an arrangement of the wire 15 and yield can be improved.

Since other configurations of the semiconductor device 1 according to the third embodiment are similar to corresponding configurations of the semiconductor device 1 according to the first embodiment, detailed descriptions thereof will be omitted.

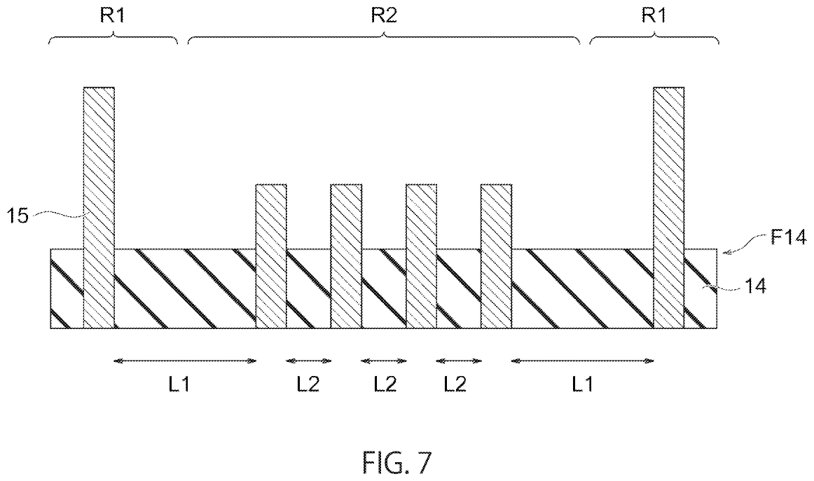

FIG. 7 is a cross sectional view showing an example of a formation method of an end of the wire 15 according to the third embodiment. FIG. 7 represents an enlarged cross sectional view in the step shown in FIG. 3E.

The formation method of the end of the wire 15 according to the third embodiment is more or less the same as the formation method of the end of the wire 15 according to the second embodiment with the exception of a height and an arrangement of the wire 15.

The plurality of the wires 15 are formed by varying heights corresponding to a density or a distance between wires 15. In the example shown in FIG. 7, the wires 15 are formed relatively high in the region R1 and relatively low in the region R2. In the example shown in FIG. 6, the width of the large-width parts 152 are relatively large in the region R1 and relatively small in the region R2.

In this manner, since the large-width part 152 is formed after forming the resin layer 14, the size (width) of the large-width part 152 can be more readily adjusted by adjusting the height of the wire 15 to be formed.

As in the third embodiment, the size of the large-width part 152 may differ in accordance with a position on the face F14. The semiconductor device 1 according to the third embodiment is capable of producing a similar effect to the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device, comprising:
a first substrate having a first face;
a resin layer which is provided on the first face and which has a second face on an opposite side to the first substrate; and
a wire which is provided so as to penetrate the resin layer and protrude from the second face, wherein
the wire has a large-width part which is provided at an end of the wire that protrudes from the second face and which has a larger width than a width of the wire that penetrates the resin layer, and
the large-width part is arranged so as to come into contact with the second face.

2. The semiconductor device according to claim 1, wherein
the wire extends in a direction approximately perpendicular to the first face.

3. The semiconductor device according to claim 1, comprising
a plurality of the wires, each including the large-width part, wherein
the plurality of the large-width parts have different sizes corresponding to positions on the second face.

4. The semiconductor device according to claim 3, wherein
the plurality of the large-width parts are electrically connected to a second substrate provided so as to oppose the second face, and
the plurality of the large-width parts have different heights corresponding to a warpage of the second substrate.

5. The semiconductor device according to claim 3, wherein
the plurality of the large-width parts have different widths corresponding to intervals between the wires on the second face.

6. The semiconductor device according to claim 5, wherein
the second face has a first region and a second region in which a density of the wire on the second face is higher than in the first region, and
a width of the large-width part in the second region is smaller than a width of the large-width part in the first region.

7. The semiconductor device according to claim 1, wherein
the large-width part is integrally configured with the wire penetrating the resin layer using a same material.

8. The semiconductor device according to claim 1, wherein
the first substrate further has a pad provided on the first face, and
the wire is provided so as to penetrate the resin layer from the pad and protrude from the second face.

9. The semiconductor device according to claim 1, further comprising
a semiconductor chip which is provided on the first face and which is covered by the resin layer, wherein
the semiconductor chip is electrically connected to the wire.

10. A manufacturing method of a semiconductor device, comprising:
forming a wire above a first face of a first substrate having the first face;
forming, on the first face, a resin layer having a second face on an opposite side to the first face so as to expose an end of the wire; and
forming a large-width part having a larger width than a width of the wire penetrating the resin layer at the end of the wire being exposed from the second face.

11. The manufacturing method of a semiconductor device according to claim 10, further comprising:
forming a plurality of the wires having different heights corresponding to a position on the first face so that the wires being exposed from the second face have different heights; and
forming the large-width part having a different size corresponding to a position on the second face at the end of each of the plurality of the wires.

12. The manufacturing method of a semiconductor device according to claim 10, further comprising:
forming the large-width part at the end of the wire being exposed from the second face by melting the end of the wire.
